(19) United States
(12) Patent Application Publication
(10) Pub. No.: US 2022/0221601 A1
(43) Pub. Date: Jul. 14, 2022

(54) FAST NEUTRON DETECTOR-Photovoltaic Sheet materials

(71) Applicant: Fusion Energy Solutions, Tempe, AZ (US)

(72) Inventors: Ian Shawn Horvath, Phoenix, AZ (US); Yiyang Li, Tempe, AZ (US); Charles Runyan, Tempe, AZ (US)

(21) Appl. No.: 17/700,472

(22) Filed: Mar. 21, 2022

Related U.S. Application Data
(62) Division of application No. 17/146,292, filed on Jan. 11, 2021, now abandoned.
(60) Provisional application No. 62/959,633, filed on Jan. 10, 2020.
(60) Provisional application No. 62/960,481, filed on Jan. 13, 2020.
(60) Provisional application No. 62/963,365, filed on Jan. 20, 2020.
(60) Provisional application No. 62/970,061, filed on Feb. 4, 2020.
(60) Provisional application No. 62/960,492, filed on Jan. 13, 2020.

(51) Int. Cl. G01T 3/08; H01L 31/0203; H01L 31/0216; H01L 31/117

(52) U.S. Cl. CPC G01T 3/08; H01L 31/117; H01L 31/02161; H01L 31/0203

(57) ABSTRACT

Fast neutron detectors using nuclear reactions within semiconductor sheet material. Some versions used doped versions of the material. Some versions use dopants selected from Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr. Some versions have filters or coatings deposited on windows into the detector. Coatings are selected from titanium oxide, zinc oxide, tin oxide, copper indium gadolinium selenide, cadmium telluride, cadmium tin oxide, perovskite photovoltaic, Si, GaAs, AlP, Ge.

### CROSS-REFERENCE TO RELATED APPLICATIONS

This application is related to and claims priority to U.S. Provisional Patent Application Numbers, all of which are incorporated by reference:
62/959,633, filed on Jan. 10, 2020
62/960,481, filed on Jan. 13, 2020
62/960,492, filed on Jan. 13, 2020
62/963,365, filed on Jan. 20, 2020
62/970,061, filed on Feb. 4, 2020
62/970,392, filed on Feb. 5, 2020
   This application is a DIVISIONAL of and claims priority to U.S. Non-Provisional patent application Ser. No. 17/146,292, filed on Jan. 11, 2021, pending, which is incorporated by reference.

### BACKGROUND

### PIPS

Standard PIPS detectors have been employed for years, quantifying charged reaction particles from nuclear reactions. PIPS detectors use the photovoltaic effect to count the number of charged particles during rated when radiation enters the detector. The particle (light ray) enters the detector and transfers some of its energy into the electrons of the detector substrate material. In this case to silicon. A key feature of PIPS detectors is that the detector responds to charged particles. The particles pass through the detector and generate mobile pairs of electrons and holes in the semiconductor substrate. Consequently, PIPS arrangements are ill-suited for detecting neutral particles, for example, neutrons.

Silicon Photomultiplier detectors (SiPM) are well known. An incoming photon generates an avalanche of charge carriers. This avalanche creates a measurable current proportional to the number of fast neutrons.

SiPM comprise a Si substrate that is sensitive to incoming photons. But the detector is also sensitive to photons generated inside the detector.

An incoming neutron will sometimes collide with a Si atom and that collision generates a quantity of photons proportional to the number flux of incoming neutrons. And the SiPM is to those photons.

### Fiberoptic

Fiberoptic cables contain long fibers of glass: essentially silica. These fibers have been designed to transmit photons and part of the transmission process is detecting those photons as they exit the fiberoptic cable.

Penetration of neutrons into the fiber produces neutrons colliding with the silicon of the silica. These collisions generate photons within the optical fibers. Photons generated in the optical fibers of the fiberoptic cable will travel through the glass and then be detected.

### Photodiodes

Photodiodes are diodes that conduct electricity when exposed to light. The silicon in the diode can interact with incoming neutrons, again generating photons that the photodiodes can detect.

### FIGURES

FIG. 1A depicts a perspective view of prior art PIPS detector.

FIG. 1B is a different view of the detector FIG. 1A.

FIG. 1C is a back view of the detector of FIG. 1A.

FIG. 2 illustrates a method of using a detector.

FIG. 3 is a prospective view of a PIPS detector according to an embodiment of the invention.

FIG. 4A is a schematic view of the PIPS substrate.

FIG. 4B depicts a side view of the PIPS substrate

FIG. 5 depicts a side view of the PIPS substrate according to an alternative version of modified PIPS substrate.

FIG. 6A depicts a side view of the PIPS substrate according to another version of modified PIPS substrate.

FIG. 6B depicts a side view of the PIPS substrate according to another version of modified PIPS substrate.

FIG. 7 depict a side view of the PIPS substrate according to an alternative embodiment of an inventive PIPS substrate.

FIG. 8 depicts a side view of the PIPS substrate according to an alternative embodiment of an inventive PIPS substrate.

FIG. 9A depicts a side view of the PIPS substrate according to an alternative embodiment of an inventive PIPS substrate.

FIG. 9B depicts a side view of the PIPS substrate according to an alternative embodiment of an inventive PIPS substrate.

FIG. 10 depicts a schematic view of a silicon photomultiplier.

FIG. 11 depicts a schematic view of a fiber optic detector.

FIG. 12 depicts a schematic view of a Silicon photodiode detector.

### DETAILED DESCRIPTION

| | |
|---|---|
| connector | 25 |
| PIPS detector case | 305 |
| detector window | 320 |
| semiconductor substrate | 410 |
| electrodes | 420, 430 |
| coating | 510 |
| dopant | 610 |

The detector element of invention detectors is an element that reacts with incoming neutrons. For instance, Si 28 facilely interacts with neutrons. This reaction yields any number of products, such as gamma rays or charged particles. These particles interact with the detector in a typical fashion. Thus, the nuclear reaction of an incoming neutron with the detector substrate creates products that the detector was designed to detect. Nonetheless, modification of the detector provides the ability to detect neutral particles more optimally, while substantially retaining the cost benefits that detectors typically provide. That is, detectors can be modified to measure the reaction products of an impinging neutron and hence indirectly quantitatively measure the number of impinging neutrons.

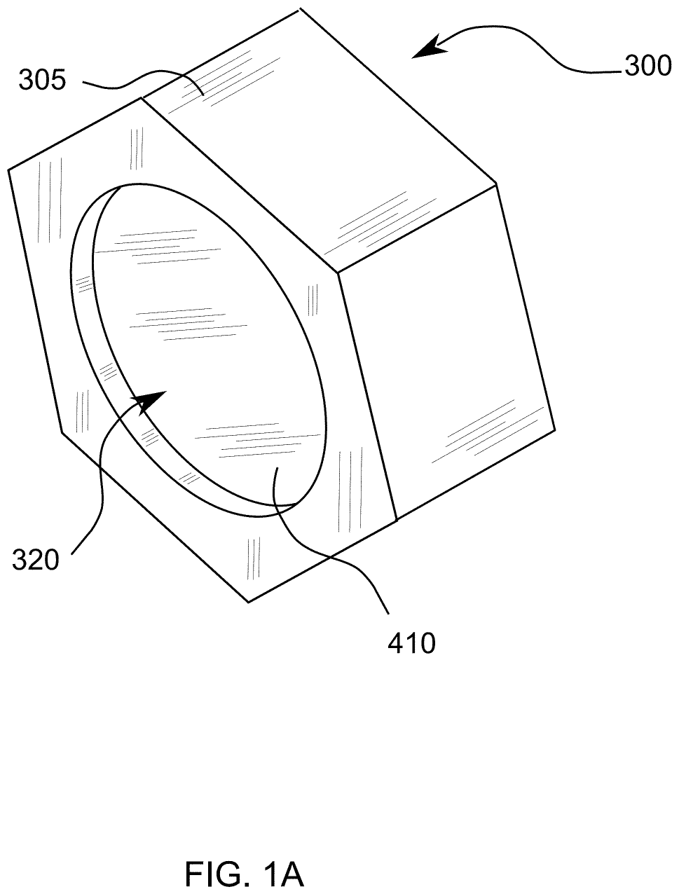

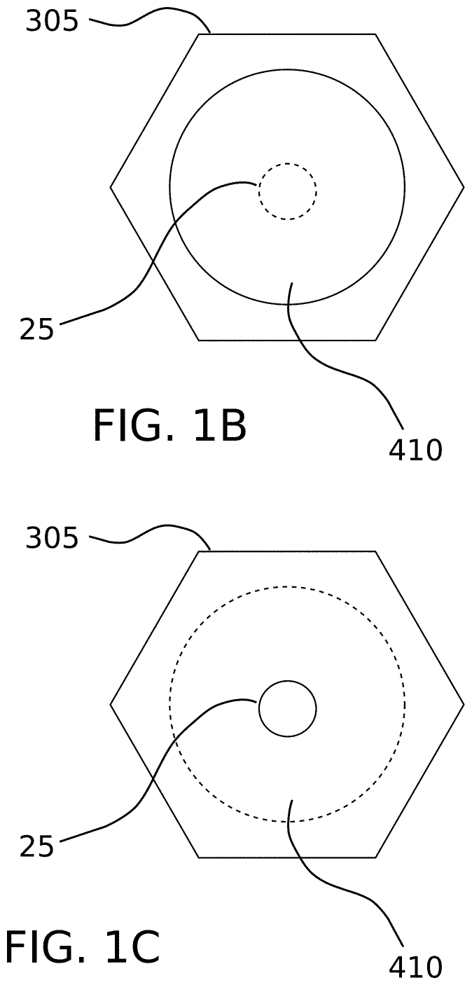

FIG. 1A depicts a PIPS detector. The figure shows detector case 305, window 320, and silicon substrate 410. FIG. 1B represents a view of the detector looking down onto the window. FIG. 1C represents a view of the detector looking at the back of the detector. Element 320 indicates a window to the detector. This is where the neutrons enter the detector. In FIGS. 1B and 1C component 25 represents an electrical connection on the back of the detector, which contains two electrodes not shown in this figure.

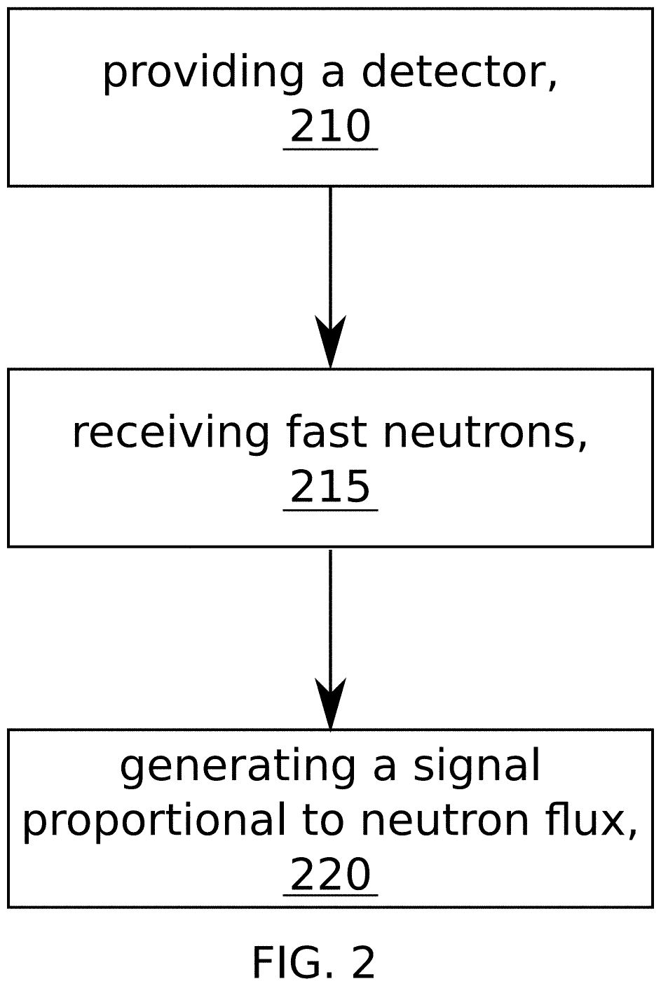

FIG. 2 represents a method of measuring fast neutrons. The first step is providing 210 a detector that has a substrate that is capable of nuclearly reacting with an income neutron. Either the bulk substrate of the detector or a coating on the detector or a dopant element implanted into the detector substrate should exhibit this nuclear reactivity. The next step is to place the detector where it can receive 215 neutrons or fast neutrons through window 320. As discussed above, the nuclear reaction generates gamma rays, among other nuclear particles, which the detector can sense. Another step is the step of generating 220 a signal proportional to the incoming neutron flux or number of neutrons.

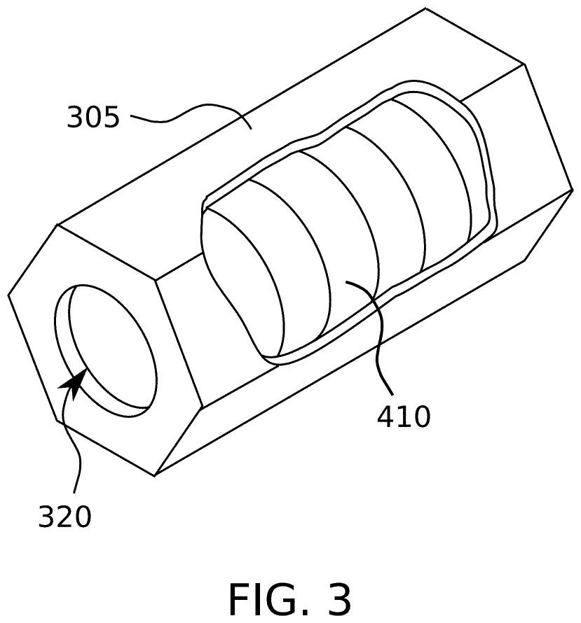

FIG. 3 depicts a detector. Detector case 305 surrounds a stack of semiconductor layers 410. The radiation that is to be measured, such as a neutron flux, enters through detector window 320. The incoming neutrons react with the semiconductor layer, sometimes silicon 28, and generates observable signals.

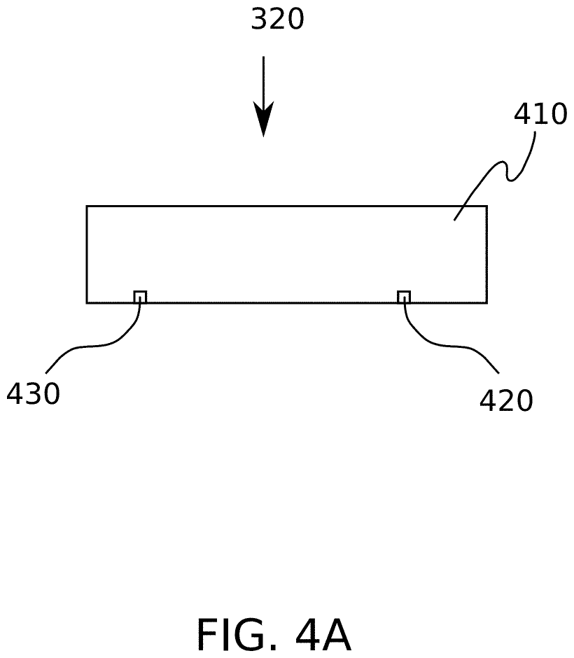

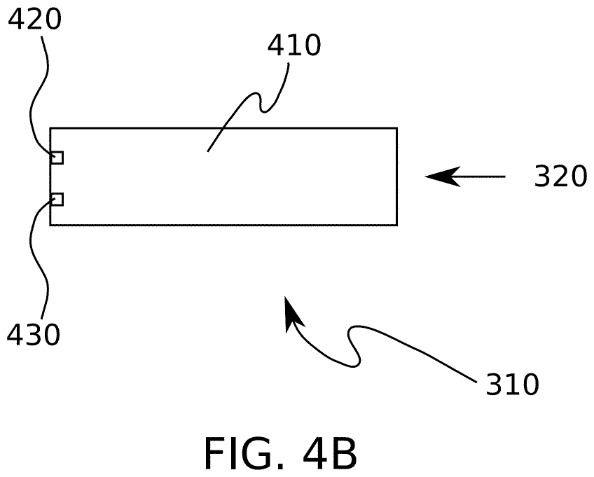

FIG. 4A is a PIPS detector depicted in schematic format. It shows window 320, substrate 410, and electrodes 420, 430. The incoming neutrons enter the detector through window 320.

FIG. 4B depicts a detector like that of FIG. 4A. It shows window 320, substrate 410, and electrodes 420, 430. In this version, Si substrate 410 is thicker or deeper. Being thicker, this version of the detector provides more opportunities for the to interact with the silicon 28.

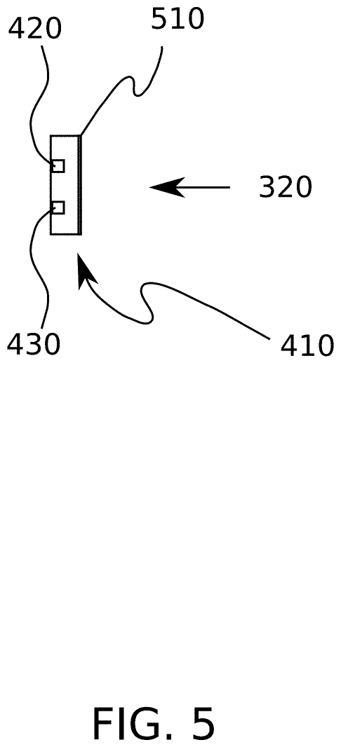

FIG. 5 depicts a standard PIPS detector with substrate 410, window 320, and electrodes 420, 430. Additionally, it contains a coating 510, which coating 510 serves a variety of functions including filtering out neutrons with energies not relevant to the experiment or measurement. Additionally, the coating can interact with to produce reactants that have different energies than the silicon 28.

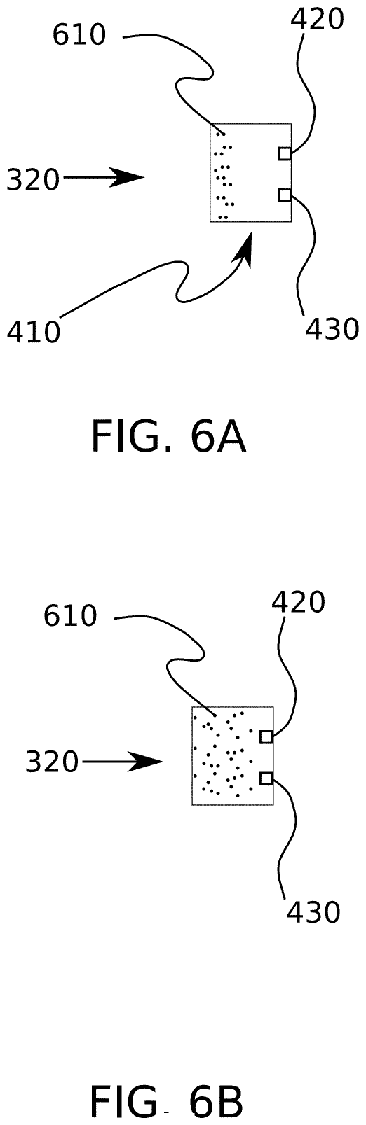

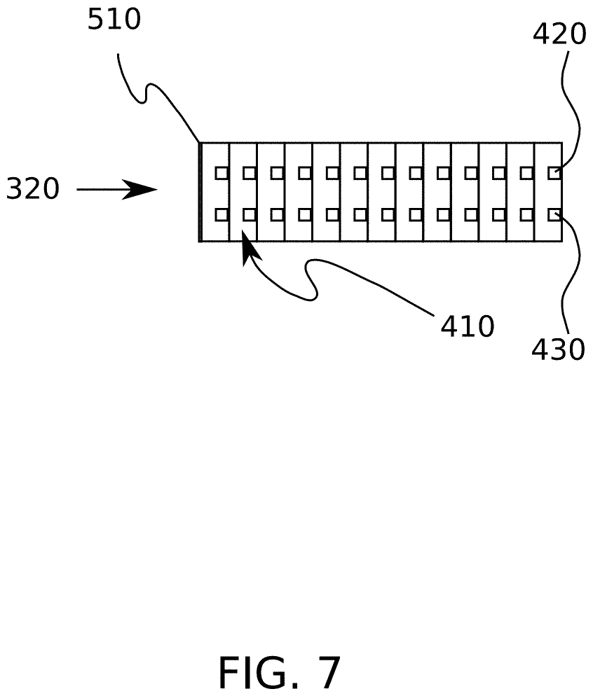

FIGS. 6A and 6B depict PIPS detector with window 320, substrate 410, and electrodes 420, 430. Additionally, these figures depict a dopant atom or element 610. FIG. 6A illustrates that dopant 610 is concentrated near the surface of detector window 320. In FIG. 6B, dopant 610 is spread throughout substrate 410.

The dopant atoms, or the nuclear reactive components of the coating, can be chosen from elements with a moderate to high cross-section for neutron absorption. In some versions, these items are chosen so that the reaction with a neutron yields nuclear particles other than neutrons. Sometimes the element reacts with the neutron to yield gamma rays. Appropriate choice of dopant element or a coating component adjusts the energy or energy range that the detector is sensitive to.

Dopants can be selected from any one or any combination of the following: Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr.

FIG. 7 depicts a detector with a stack of individual semiconductor substrate 410 layers where each of substrate 410 have functional electrodes 420, 430. Detector electrodes connect to supporting electronics, such as amplifiers, preamplifiers, etc. The figure depicts window 320 and coating 510, as described above.

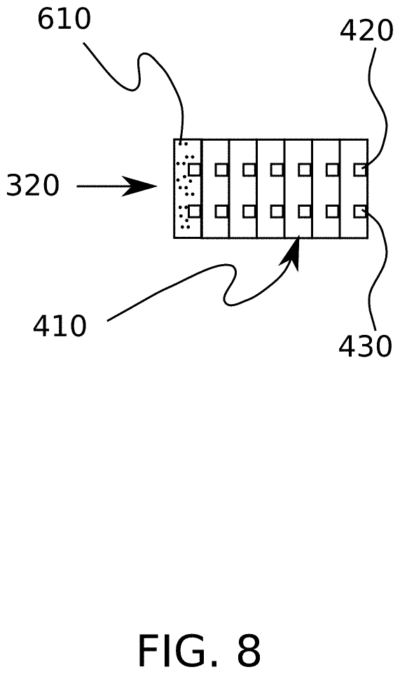

FIG. 8 depicts a detector like that shown in FIG. 7 with dopant 610 located in the topmost substrate layer 410.

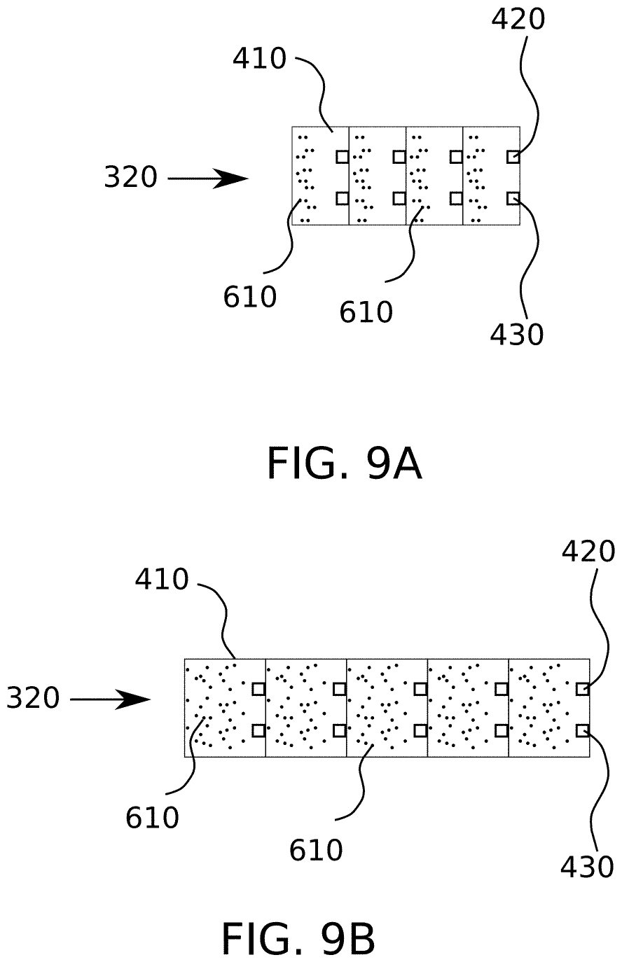

FIG. 9A depicts a stacked detector showing electrodes 420, 430. It also shows a stack of substrate 410 and window 320. In this case, dopant 610 is in a top layer of the substrate 410 in two or more individual layers of substrate 410.

FIG. 9B shows a detector that is like the detector of FIG. 9A. It depicts a stacked detector showing electrodes 420, 430. It also shows a stack of substrate 410 and window 320. In this case, dopant 610 is spread throughout the substrate 410 in two or more individual layers of substrate 410.

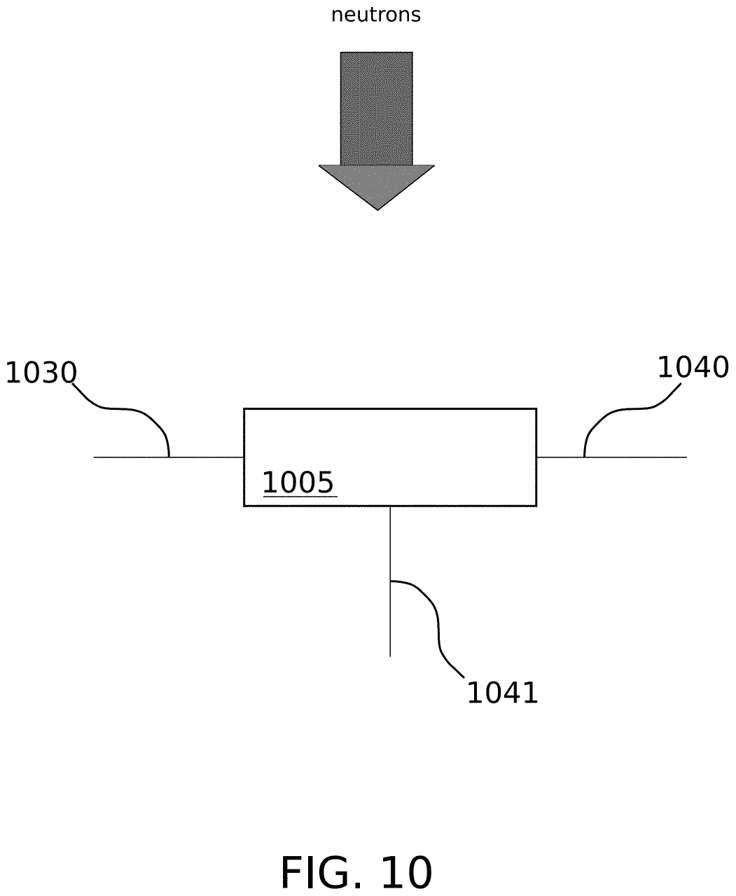

FIG. 10 depicts a schematic view of an SiPM 1005 arranged to detect a neutron flux. SiPM 1005 has electrodes 1030, 1040 for applying a bias or operating voltage. Contact 1041 is an output contact. This contact connects to an amplifier for detecting the signal generated by SiPM. In incoming neutron interacts with silicon 28 contained in the SiPM generating gamma rays or other reactants that eventually create pairs, and the SiPM multiplies that signal.

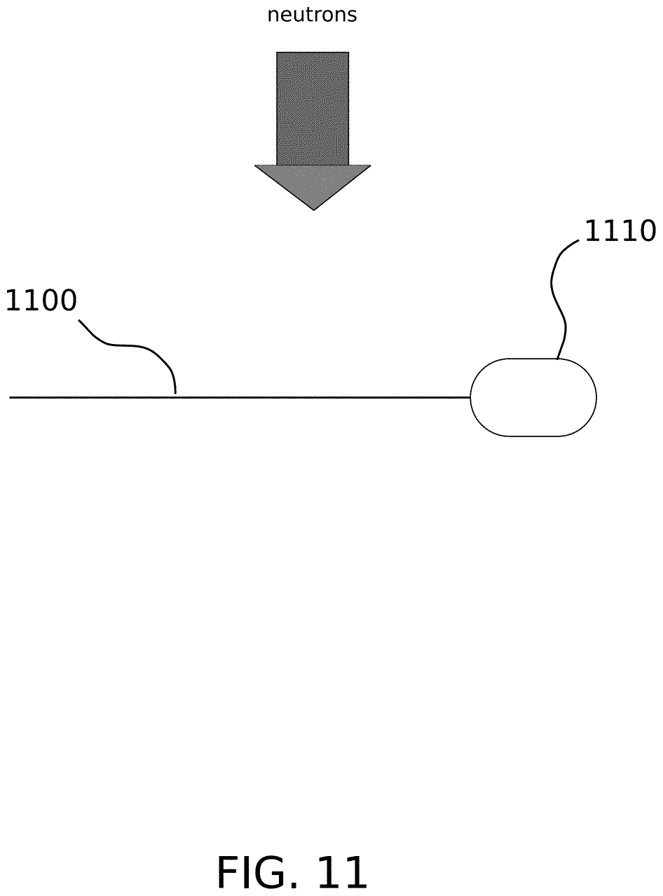

FIG. 11 depicts a schematic view of the fiberoptic detector 1105. Fiber 1120 connects to transceiver 1110. Incoming neutrals react with the silicon contained in the silicon dioxide or silica of the glass in the fiber. The reaction produces gamma rays the photons of which travel down the glass fiber to be detected by transceiver 1110. Or the reaction produces other particles.

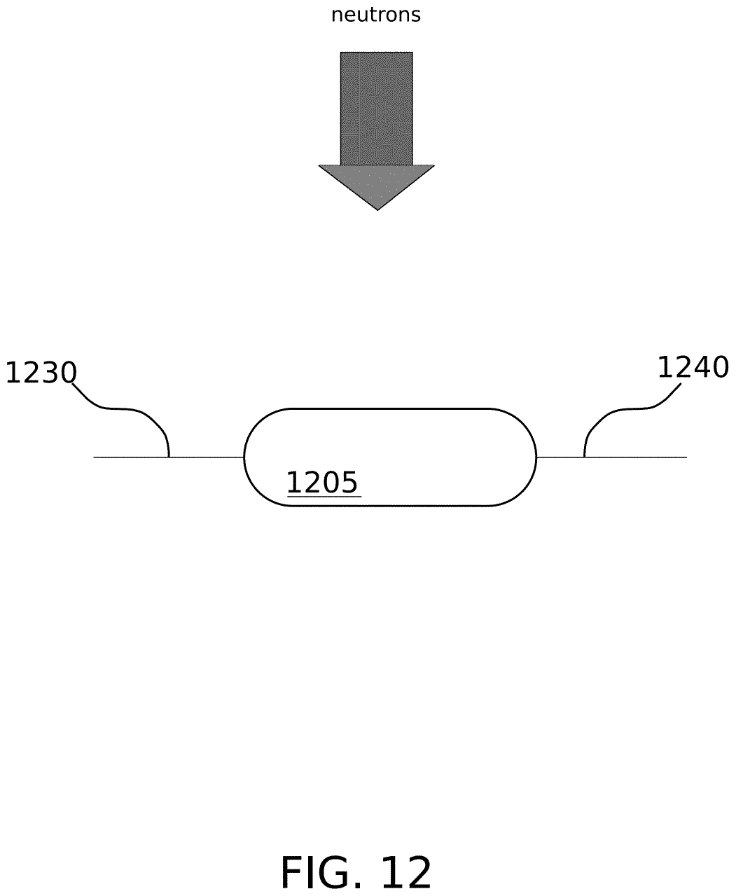

FIG. 12 depicts a schematic view of the photodiode detector 1205. Detector 1205 has electrodes 1230, 1240. Incoming neutrons react with the silicon 28 contained in the substrate of the photodiode.

The previous description of several embodiments describes non-limiting examples that further illustrate the invention. All titles of sections contained in this document, including those appearing above, are not to be construed as limitations on the invention, but rather they are provided to structure the illustrative description of the invention that is provided by the specification.

Unless defined otherwise, all technical and scientific terms used in this document have the same meanings as commonly understood by one skilled in the art to which the disclosed invention pertains. Singular forms—a, an, and the—include plural referents unless the context clearly indicates otherwise. Thus, for example, reference to “fluid” refers to one or more fluids, such as two or more fluids, three or more fluids, etc. When an aspect is said to include a list of components, the list is representative. If the component choice is specifically limited to the list, the disclosure will say so. Moreover, listing components acknowledges that embodiments exist for each of the components and any combination of the components—including combinations that specifically exclude any one or any combination of the listed components. For example, “component A is chosen from A, B, or C” discloses embodiments with A, B, C, AB, AC, BC, and ABC. It also discloses (AB but not C), (AC but not B), and (BC but not A) as embodiments, for example. Combinations that one of ordinary skill in the art knows to be incompatible with each other or with the components' function in the invention are excluded from the invention, in some embodiments.

The terminology used herein is to describe particular example embodiments only and is not intended to be limiting. As used herein, the singular forms “a”, “an” and “the” may be intended to include the plural forms as well, unless the context clearly indicates otherwise. The terms “comprises”, “comprising”, “including”, and “having”, are inclusive and therefore specify the presence of stated features, integers, steps, operations, elements, and/or components, but do not preclude the presence or addition of one or more other features, integers, steps, operations, elements, components, and/or groups. The method steps, processes, and operations described herein are not to be construed as necessarily requiring their performance in the particular order discussed or illustrated, unless specifically identified as an order of performance. It is also to be understood that additional or alternative steps may be employed,

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on”, “directly engaged to”, “directly connected to” or “directly coupled to” another element or layer, there may be no intervening elements or layers present. Other words used to describe the relationship between elements should be interpreted in a like fashion (e.g., “between” versus “directly between”, “adjacent” versus “directly adjacent”, etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer, or section. Terms such as “first”, “second”, and other numerical terms when used herein do not imply a sequence or order unless clearly indicated by the context. Thus, a first element, component, region, layer, or section discussed below could be termed a second element, component, region, layer, or section without departing from the teachings of the example embodiments.

Spatially relative terms, such as “inner”, “outer”, “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Moreover, some embodiments recite ranges. When this is done, it is meant to disclose the ranges as a range, and to disclose each and every point within the range, including end points. For those embodiments that disclose a specific value or condition for an aspect, supplementary embodiments exist that are otherwise identical, but that specifically exclude the value or the conditions for the aspect.

The embodiments of the invention described herein are exemplary and numerous modifications, variations and rearrangements can be readily envisioned to achieve substantially equivalent results, all of which are intended to be embraced within the spirit and scope of the invention. Further, the purpose of the foregoing abstract is to enable the U.S. Patent and Trademark Office and the public generally, and especially the scientist, engineers and practitioners in the art who are not familiar with patent or legal terms or phraseology, to determine quickly from a cursory inspection the nature and essence of the technical disclosure of the application.

The following description of several embodiments describes non-limiting examples that further illustrate the invention. No titles of sections contained herein, including those appearing above, are limitations on the invention, but rather they are provided to structure the illustrative description of the invention that is provided by the specification.

Any methods and materials similar or equivalent to those described in this document can be used in the practice or testing of the present invention. This disclosure incorporates by reference all publications mentioned in this disclosure and all of the information disclosed in the publications.

This disclosure discusses publications only to facilitate describing the current invention. Their inclusion in this document is not an admission that they are effective prior art to this invention, nor does it indicate that their dates of publication or effectiveness are as printed on the document.

1. A nuclear detector comprising:
a case with an opening,
a receiving axis extending out from the opening,
PV sheets each comprising electrodes,
wherein the sheets stack coaxially along the receiving axis perpendicular to the receiving axis and wherein the electrodes connect to the supporting electronics.

2. The detector of claim 1, wherein the PV sheets further comprise a coating.

3. The detector of claim 2, wherein the coating comprises a material selected from any one or any combination of the following: Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr.

4. The detector of claim 3, wherein the coating comprises a material selected from any one or any combination of the following: Ba, As, Ce, Co, Cu, Ga, Ge, In, Cd, Al, K, La, Mo, Nd, Os, Pr, I, Sn, Sr, Ti, V, Zn, and Zr.

5. The detector of claim 2, wherein the coating comprises a material selected from any one or any combination of the following: titanium oxide, zinc oxide, tin oxide, ClGdSe, cadmium telluride, cadmium tin oxide, perovskite PV, Si, GaAs, AlP, Ge.

6. The detector of claim 1, further comprising a dopant ion-implanted into at least one sheet, wherein the dopant comprises a material selected from any one or any combination of the following: Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr.

7. The detector of claim 6, wherein the dopant comprises a material selected from any one or any combination of the following: Ba, As, Ce, Co, Cu, Ga, Ge, In, Cd, Al, K, La, Mo, Nd, Os, Pr, I, Sn, Sr, Ti, V, Zn, and Zr.

8. The detector of claim 6, wherein the coating comprises a material selected from any one or any combination of the following: titanium oxide, zinc oxide, tin oxide, ClGdSe, cadmium telluride, cadmium tin oxide, perovskite PV, Si, GaAs, AlP, Ge.

9. The detector of claim 7, wherein the sheet sits perpendicular to the receiving axis and the coating comprises a material selected from any one or any combination of the following: Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr.

10. The detector of claim 9, wherein the coating comprises a material selected from any one or any combination of the following: Ba, As, Ce, Co, Cu, Ga, Ge, In, Cd, Al, K, La, Mo, Nd, Os, Pr, I, Sn, Sr, Ti, V, Zn, and Zr.

11. The detector of claim 7, wherein the coating comprises a material selected from any one or any combination of the following: titanium oxide, zinc oxide, tin oxide, ClGdSe, cadmium telluride, cadmium tin oxide, perovskite PV, Si, GaAs, AlP, Ge.

12. The detector of claim 2, wherein the PV sheet has a dopant ion-implanted into the sheet, the sheet sits perpendicular to the receiving axis, and the dopant comprises a material selected from any one or any combination of the following: Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr.

13. The detector of claim 12, wherein the dopant comprises a material selected from any one or any combination of the following: Ba, As, Ce, Co, Cu, Ga, Ge, In, Cd, Al, K, La, Mo, Nd, Os, Pr, I, Sn, Sr, Ti, V, Zn, and Zr.

14. The detector of claim 12, wherein the coating comprises a material selected from any one or any combination of the following: titanium oxide, zinc oxide, tin oxide, ClGdSe, cadmium telluride, cadmium tin oxide, perovskite PV, Si, GaAs, AlP, Ge.

15. A nuclear detector comprising:
a case with an opening,
a receiving axis,
PV sheets at least one sheet comprising electrodes,
and
a coating comprising a material selected from any one or any combination of the following Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr,
wherein the at least one sheet sits perpendicular to the receiving axis.

16. The detector of claim 15, wherein at least one sheet comprising electrodes and a coating, the at least one sheet sits perpendicular to the receiving axis, and the coating comprises a material selected from any one or any combination of the following: titanium oxide, zinc oxide, tin oxide, ClGdSe, cadmium telluride, cadmium tin oxide, perovskite PV, Si, GaAs, AlP, Ge.

17. The detector of claim 16, wherein the PV sheets have a dopant ion-implanted into at least one sheet, the at least one sheet sits perpendicular to the receiving axis, and the dopant comprises a material selected from any one or any combination of the following: Ba, As, Br, C, Ce, Cl, Co, Cu, F, Ga, Ge, In, Cd, Te, Al, P, K, La, Mo, Nd, O, Os, Pr, S, Se, Si, Sn, Sr, Ti, Tl, V, Zn, and Zr.

18. The detector of claim 16, wherein the PV sheet has a dopant ion-implanted into at least one sheet, the at least one sheet sits perpendicular to the receiving axis, and the dopant comprises a material selected from any one or any combination of the following: Ba, As, Ce, Co, Cu, Ga, Ge, In, Cd, Al, K, La, Mo, Nd, Os, Pr, I, Sn, Sr, Ti, V, Zn, and Zr.

19. The detector of claim 16, wherein the PV sheets have a dopant ion-implanted into at least one sheet, the at least one sheet sits perpendicular to the receiving axis, and the coating comprises a material selected from any one or any combination of the following: titanium oxide, zinc oxide, tin oxide, ClGdSe, cadmium telluride, cadmium tin oxide, perovskite PV, Si, GaAs, AlP, Ge.

20. The detector of claim 19, wherein the semiconductor sheets each comprise electrodes, the sheets stack coaxially along the receiving axis perpendicular to the receiving axis, and the electrodes connect to the supporting electronics.
